(19) United States
(12) Patent Application Publication
(10) Pub. No.: US 2026/0303042 A1
(43) Pub. Date: Oct. 1, 2026

(54) MULTI-PATHS AMPLIFIER CIRCUIT

(71) Applicant: STMicroelectronics International N.V., Geneva (CH)

(72) Inventor: Gregory Wagner, Saint Blaise du Buis (FR)

(21) Appl. No.: 19/564,877

(22) Filed: Mar. 12, 2026

(30) Foreign Application Priority Data
Mar. 31, 2025 (FR) FR2503287

(51) Int. Cl. H03F 3/21; H03F 3/38; H03K 3/037; H03K 19/21

(52) U.S. Cl. CPC H03F 3/211; H03F 3/38; H03K 3/037; H03K 19/21; H03F 2200/171

(57) ABSTRACT

The present disclosure relates to an amplifier circuit having multiple amplifying paths among which a first amplification path has a notch filter, the amplifier circuit including a control circuit configured to: turn the notch filter conductive when a rate of variation in voltage of a signal present at an input node to the amplifier circuit is detected as being greater than a slew rate of the amplifier circuit; and following the detection, control the notch filter in a sampling mode after a number of periods of a first clock signal.

### CROSS-REFERENCE TO RELATED APPLICATIONS

This application claims the benefit of French Application No. FR2503287, filed on Mar. 31, 2025, which application is hereby incorporated by reference herein in its entirety.

### TECHNICAL FIELD

The present disclosure generally relates to amplifier circuits having multiple amplification paths and associated operating methods.

### BACKGROUND

Precision amplifier circuits with low offset voltage are used in many electronic assemblies, such as follower or inverter assemblies. However, these amplifiers can suffer from a settling time and temporary ripple, when a voltage step appears at their input, before the output voltage settles. This settling time of today's amplifier circuits is too high compared to the gain-band product displayed by the amplifier.

### SUMMARY

There is a desire to reduce the time needed to settle precision amplifier circuits during a step response.

One embodiment overcomes all or some of the drawbacks of known amplifier circuits.

One embodiment provides an amplifier circuit having multiple amplifying paths among which a first amplification path has a notch filter, the amplifier circuit including a control circuit configured to: turn the notch filter conductive when a rate of variation in voltage of a signal present at an input node of the amplifier circuit is detected as being greater than a slew rate of the amplifier circuit; and following the detection, control the notch filter in a sampling mode after a number of periods of a first clock signal.

One embodiment provides a method for operating a multi-paths amplifier circuit comprising a first amplification path having a notch filter and a control circuit, the method comprising: turning, using the control circuit, the notch filter conductive when a rate of variation in voltage of a signal present at an input node of the amplifier circuit is detected as being greater than a slew rate of the amplifier circuit; and following the detection, controlling using the control circuit, the notch filter in a sampling mode after a given number of periods of a first clock signal.

According to one embodiment, the amplifier circuit comprises a detection circuit: coupling an output node of the amplifier circuit having multiple amplification paths to an input node of the control circuit; and comprising a comparator circuit coupling a high-pass filter to the input node of the control circuit; or wherein said number of periods is programmable.

According to one embodiment, the comparator circuit is configured to compare the signal at the output of the high-pass filter with one or more voltage thresholds, for example programmed from outside the amplifier circuit, and if one of these thresholds is crossed, then the signal state at the input node of the control circuit is changed, for example in the form of a pulse.

According to one embodiment, the control circuit comprises a latch: a first input node of which is coupled to the input node of the control circuit; and a second input node of which is coupled to a third node.

According to one embodiment, the control circuit comprises at least one flip-flop coupling a first output node of the latch to the third node, and configured to receive the first clock signal.

According to one embodiment, the control circuit comprises several series-connected flip-flops coupling the first output node of the latch to the third node, a first flip-flop among said several flip-flops being configured to receive the first clock signal, and a second flip-flop among said several flip-flops being configured to be controlled by a complementary signal of the first clock signal.

According to one embodiment, the latch is of the RS-type.

According to one embodiment, the control circuit comprises a first logic circuit configured to implement an XOR-type function between the signal present at the third node and the signal present at the input node of the control circuit.

According to one embodiment, the notch filter comprises: a first branch comprising a first and a second switches, in series between a fourth and a fifth nodes of the first amplification path, and configured to be respectively controlled by first and second control signals, a mid-point between the first and second switches being grounded through a first capacitor; and a second branch comprising a third and a fourth switches, in series between the fourth and fifth nodes, and configured to be respectively controlled by the second and first control signals, a mid-point between the third and fourth switches being grounded through a second capacitor; the first and second control signals being generated by the control circuit.

According to one embodiment, an output node of the first logic circuit is coupled to a second logic circuit, and to a third logic circuit; the second logic circuit being configured to implement an OR-type function between the signal present at the output node of the first logic circuit and a third control signal, the signal present at the output of the second logic circuit being the first control signal; the third logic circuit being configured to implement an OR-type function between the signal present at the output node of the first logic circuit and a fourth control signal, the signal present at the output of the third logic circuit being the second control signal; the third and fourth control signals being in phase opposition, and having a period twice the period of the first clock signal; the third and fourth control signals being used for the sampling mode

According to one embodiment, the amplifier circuit comprises a first resistor in series with a third capacitor between the fourth node and a sixth node; a fifth switch, configured to be controlled by the signal present at the output node of the first logic circuit, is arranged in parallel with the first resistor.

According to one embodiment, the amplifier circuit comprises a second resistor in series with a fourth capacitor between a seventh node and the sixth node; a sixth switch, configured to be controlled by the signal present at the output node of the first logic circuit, being arranged in parallel with the second resistor; the output node of the first amplification path being the mid-point between the second resistor and the fourth capacitor.

According to one embodiment, the first amplification path comprises a first amplifier that couples to a first chopper circuit configured to implement modulation and to a second chopper circuit configured to implement demodulation; the first and second chopper circuits are configured to operate at the frequency of said first clock signal.

According to one embodiment, the first amplification path comprises a second amplifier coupling the fifth node to the seventh node; a second amplification path of the multi-path amplifier circuit comprises a third amplifier coupling the seventh node to the input node of the multi-path amplifier circuit; and a fourth amplifier of the multi-path amplifier circuit couples the sixth node to the seventh node.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a schematic of an inverting amplification assembly to which the embodiments can be applied;

FIG. 2 is a schematic of an amplifier architecture used in the assembly shown in FIG. 1, according to an embodiment of the disclosure;

FIG. 3 is an operating timing diagram for the circuit shown in FIG. 2, according to an embodiment of the disclosure;

FIG. 4 is a schematic of an amplifier architecture in the assembly shown in FIG. 1 with improved settling time, according to an embodiment of the disclosure; and

FIG. 5 is an operating timing diagram for the circuit shown in FIG. 4, according to an embodiment of the disclosure.

### DETAILED DESCRIPTION OF ILLUSTRATIVE EMBODIMENTS

Like features have been designated by like references in the various figures. In particular, the structural and/or functional features that are common among the various embodiments may have the same references and may dispose of identical structural, dimensional, and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially,” and “in the order of” signify within 10% or 10°, and preferably within 5% or 5°.

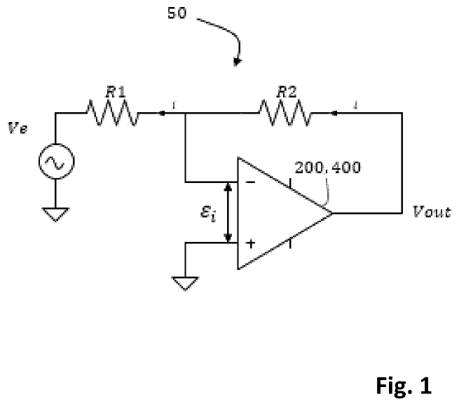

FIG. 1 schematically illustrates an amplifier assembly 50 to which the embodiments can be applied.

The amplifier assembly 50 is an inverter-type assembly. In the illustrated example, an amplifier circuit 200, 400 comprises an inverting input (denoted−) and a grounded non-inverting input (denoted+), between which a potential difference εᵢ may occur. An output node of the amplifier circuit 200, 400 is coupled to the inverting input via a resistor of value R2. The inverting input is coupled to a voltage rail via a resistor of value R1, configured to receive a voltage Ve, referenced to ground.

The output voltage Vout of amplifier assembly 50 corresponds to the ratio of the values—R2 and R1 multiplied by voltage Ve.

When a rate of variation in the potential difference εᵢ occurring between the non-inverting and inverting inputs is rapid, i.e. greater than an amplifier slew rate, the voltage at output then “oscillates” for a settling time until the voltage Vout settles at 0.1 or 0.01% of the setpoint. A voltage-variation rate means a variation in voltage per unit of time, expressed in V/μs, for example. The slew rate (also known as slew speed) of an amplifier, for example, is defined as the maximum rate of variation in the amplifier output voltage, and is expressed in V/μs, for example. The slew rate is measured by applying a large signal step, such as one volt, to the amplifier input and measuring the rate of variation from 10% to 90% in the output signal amplitude.

When the settling time is too long, i.e., greater than the theoretical settling time of the amplifier, which is linked to its gain-band product, circuit performance, such as accuracy, is degraded.

The slow settling time of amplifier circuits can affect many types of assembly, such as analog-to-digital converters (ADCs) and others.

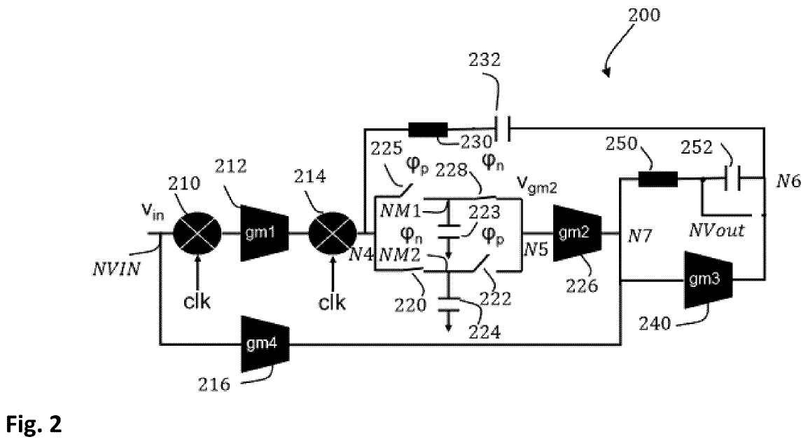

FIG. 2 schematically illustrates a multipath amplifier architecture 200 used in the assembly shown in FIG. 1.

The amplifier circuit 200 comprises two amplification paths. A first amplification path comprises an amplifier 212 (gm1) coupling a first chopper circuit 210 configured to implement modulation, and a second chopper circuit 214 configured to implement demodulation. The first and second chopper circuits are configured to operate at the frequency of a first clock signal clk. The first chopper circuit 210 is coupled, preferably connected, to an input node NVIN of the amplifier circuit 200. The second chopper circuit 214 is coupled, preferably connected, to a node N4.

The frequency of the signal clk is, for example, several hundred kHz or even a few MHz.

The chopper circuits 210, 214 are configured to perform chopping, or trimming, which is a continuous time modulation technique that does not cause noise aliasing. They allow the input voltage Vin offset, as well as low-frequency or flicker noise, i.e., noise at 0 Hz, to be eliminated.

At the output of the chopper circuit 214, the signal may, however, have a saw tooth effect due to the modulation of the offset voltage by the chopper circuit, thus generating ripple. Several solutions can be implemented to limit these phenomena. A filter can be implemented, but this limits bandwidth and stability by adding an extra pole. In addition, integrating passive components increases the silicon surface area.

A notch filter can also be used. The ripple caused by the input voltage offset is thus filtered out by the notch filter, yielding a constant voltage.

Thus, in the illustrated example, the first amplification path also comprises a notch filter. The notch filter comprises, for example, a first branch formed of a first switch 225 and a second switch 228, in series between node N4 and node N5. The first switch 225 and the second switch 228 are, for example, configured to be controlled, in a sampling mode, by control signals respectively referred to as φₚ, φₙ. The control signals φₚ, φₙ are, for example, in phase opposition, and with a period equal to or twice the period of the first clock signal clk. A midpoint NM1 between the first and second switches is grounded through a capacitor 223.

The notch filter also comprises, for example, a second branch consisting of a third switch 220 and a fourth switch 222, in series between node N4 and node N5. The third switch 220 and the fourth switch 222 are configured, for example, to be controlled in the sampling mode by the control signals φₙ, φₚ, respectively. The midpoint NM2 of the third switch 220 and the fourth switch 222 is grounded through a capacitor 224.

In one example, the control signals φₙ, φₚ are generated by an additional internal circuit at the core of the amplifier 200 (clock generator).

In one example of the sampling mode, the control signals φₙ, φₚ have a frequency between 10 kHz and 100 kHz. In the event of a rapid variation in input voltage or in input signal frequency, this sampling frequency slows down the response of the circuit 200 beyond the expected time constant. In addition, the output error of the chopper circuit 214 is maintained during each notch filter period (e.g., 10 μs for 100 kHz sampling). On the other hand, it is not possible to increase the sampling frequency indefinitely, as this has an impact on signal ripple.

In the illustrated example, the first amplification path further comprises an amplifier 226 (gm2) coupling node N5 to a node N7. The amplifier gm2 enables the sum of the currents of the first amplification path and a second amplification path of the multi-path amplifier circuit 200.

In the illustrated example, the second amplification path comprises an amplifier 216 (gm4) coupling the seventh node N7 to the input node NVIN of the amplifier circuit 200.

In the illustrated example, and optionally, the amplifier circuit 200 comprises a resistor 230 in series with a capacitor 232 between node N4 and node N6, allowing ripple to be reduced at the amplifier output.

In the illustrated example, and optionally, the amplifier circuit 200 comprises a compensation resistor 250 in series with a stabilizing capacitor 252 between node N7 and node N6.

In some embodiments, capacitor 232 and 252 are Miller stabilization capacitors.

The second amplification path is more rapid than the first amplification path when the first amplification path is in sampling mode, and is mostly used when the input signal frequency is above 100 kHz. The first amplification path has, in turn, a high gain equal to tgm2*tgm1/C232, where tgm1 and tgm2 are the respective transconductances of the amplifiers gm1 and gm2, and C232 is the value of the Miller stabilizing capacitor 232 of the amplifier.

In the illustrated example, the multi-path amplifier circuit 200 comprises an amplifier 240 (gm3) which couples node N7 to node N6. The amplifier gm3 is class AB, for example, and forms a power stage for the output of the multi-path amplifier circuit 200.

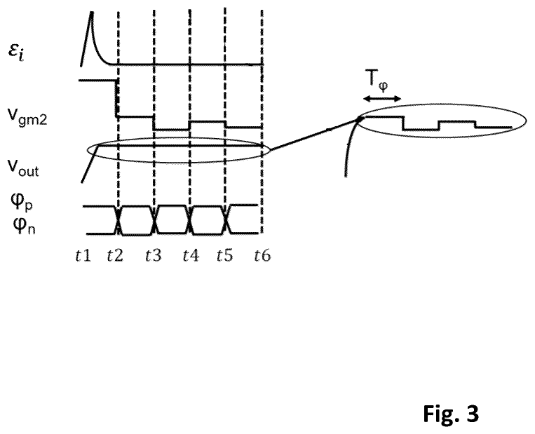

FIG. 3 illustrates an operating timing diagram for circuit 200 shown in FIG. 2. In particular, the timing diagram shown in FIG. 3 illustrates the time variations in the potential difference εᵢ, in the voltage Vgm2 present at node N5, in the voltage Vout at node NVout, and in the control signals φₚ, φₙ.

FIG. 3 also illustrates an enlarged view of the voltage Vout. At a time t1, the potential difference εᵢ changes abruptly in the form of a pulse peak, then drops rapidly until it returns to approximately the starting level at a time t2.

Shortly after time t1, amplifier 216 begins to force the voltage Vout to converge, which increases towards its final value. The first amplification path also reacts, but more slowly, and the voltage Vgm2 goes from a high level to a low level at time t2, then oscillates.

Between times t1 and t2, signal φₚ is at a high level and signal φₙ is at a low level. The levels of signals φₚ, φₙ then alternate, in phase opposition, between time t2 and a time t3, then between time t3 and a time t4, then between time t4 and a time t5, and between time t5 and a time t6. The times t2, t3, t4, t5, and t6 correspond to the half-periods of the signals φₚ, φₙ.

The error is sampled at each half-period of the signals φₚ, φₙ, which results in an error on the voltage Vgm2 for each half-period T_{φ}. The voltage Vgm2 thus varies, between times t2 and t6, between a first level and a second level, between each half-period T_{φ}. As can be seen in the enlarged view, the voltage NVout varies in the same way as the voltage Vgm2. Since the frequency of the sampling mode must remain below the unit frequency of the amplifier circuit 200, which is the frequency at which the amplifier has unit gain, this leads to a settling time that can be several times the half-period T_{φ}, i.e. several tens of μs, which is much longer than the desired settling time, which is rather less than μs, e.g. 100 ns.

In a non-illustrated example, in order to improve settling time, it is also possible to set up a ripple cancellation loop which, when a large variation (above 200 mV, for example) is detected by a comparator at the output of an input amplifier gm1 at node N4 of the high-gain path, then: an amplifier drives an output capacitor, a drift cancellation loop is disconnected, and the gain of a second amplifier stage is increased. However, this solution requires an active amplifier that can be switched on or off very rapidly, and which has a much shorter settling time than the amplifier circuit. In addition, the detection range (above 200 mV, for example) is large. Driving a capacitor injects noise into the loop. The precision of the capacitor and the switch controlling it is critical. Power consumption is also higher with this solution.

To overcome the drawbacks described in the above examples, the embodiments provide an amplifier circuit with multiple amplification paths, among which a first amplification path has a notch filter, the amplifier circuit including a control circuit configured to:
turn the notch filter conductive (i.e., on) when a voltage-variation rate of a signal present at an input node of the amplifier circuit is detected to be greater than a slew rate of the amplifier circuit; and following detection, control the notch filter in a sampling mode after a number of periods of a first clock signal.

The voltage-variation rate is the variation in voltage per unit of time. Here, the voltage-variation rate is detected, for example, when the voltage varies rapidly, i.e. by more than 0.1 V/μs.

This enables the first amplification path to react like a linear amplifier during the voltage variation, by setting the notch filter into “track” mode, i.e., turning it conductive. After the voltage-variation rate has been detected, for one or more clock strokes, with the notch filter still in track mode, the capacitors are charged directly with low error. This accelerates the transfer function of the first amplification path. This reduces the settling time. The duration of the track mode depends, for example, on the number of flip-flops and the clock frequency, but it can also be programmed. The fact that the track mode duration is a multiple of the number of clock signal periods enables synchronized resumption of the notch filter sampling mode.

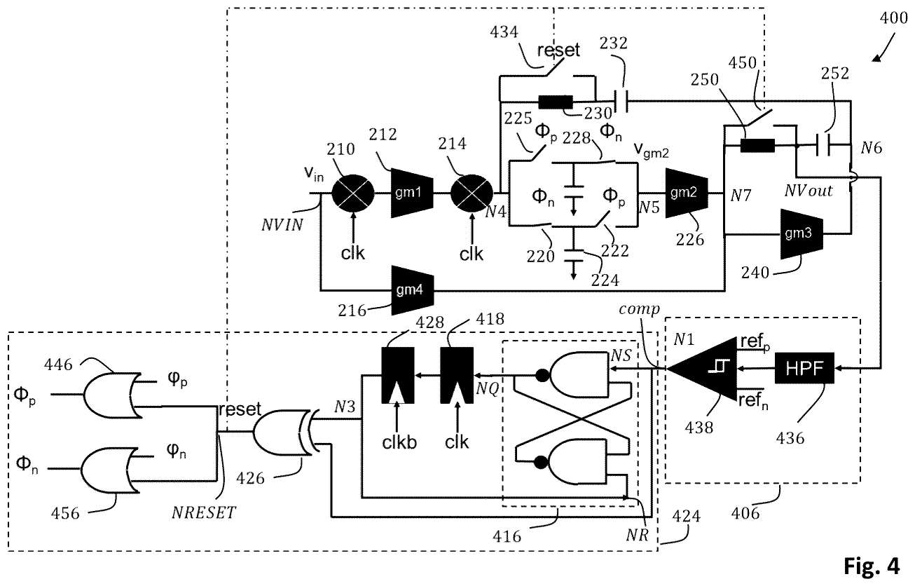

FIG. 4 schematically illustrates a circuit in the assembly shown in FIG. 1. In particular, FIG. 4 illustrates an example amplifier circuit 400.

The amplifier circuit 400 is similar to the circuit 200 shown in FIG. 2 except for the addition of a control circuit 424, coupled to the node NVout via a detection circuit 406. Compared with circuit 200, the amplifier circuit 400 further optionally comprises a switch 434, coupling a midpoint between resistor 230 and capacitor 232 to node N4. In addition, the amplifier circuit 400 optionally comprises a switch 450 coupling node N7 to node NVout.

The function of the detection circuit 406 is to determine whether a rate of variation in the output signal exceeds a slew rate of the amplifier 400, for example, during the slew phase of the amplifier circuit 400. A high slew rate is understood to be a rapid variation in voltage.

The detection circuit 406 can detect a voltage variation rate at the input node NVIN based on the signal present at node NVout. Indeed, the signal at node NVout forms an image of the variation in the input signal to the amplifier circuit 400, so it is possible, as illustrated, to couple the detection circuit 406 to node NVout to perform the detection. A rapid variation in the input signal to amplifier circuit 400 can thus be detected by detection circuit 406. In other words, a rate of variation in the voltage at the input node NVIN, greater than the slew rate of the amplifier 400, can be detected by the detection circuit 406.

In one example, the detection circuit 406 couples the output node NVout of the amplifier circuit 400 to an input node N1 of the control circuit 424.

In one example, the detection circuit 406 comprises a comparator circuit 438 coupling a high-pass filter (HPF) 436 to the input node N1 of the control circuit 424. The high-pass filter 436 has, for example, a cut-off frequency of the order of 1 MHz. High-pass filter 436 is implemented, for example, with an RC-type filter.

Upon a rapid variation in the input signal to the amplifier circuit 400, a pulse propagates through the amplifier circuit 400. This component is not filtered out by the high-pass filter 436 and is compared, by the comparator 438, with a voltage threshold(s) refp, refn. Thus, if this pulse crosses said voltage threshold(s) (positive or negative) refp, refn, then the state of the signal at input node N1 of the control circuit is changed. In one example, the levels refp and refn are of the order of one or more hundred mV, for example, 200 mV.

In the illustrated example, control circuit 424 comprises a latch 416, for example of the RS type, with a first input node NS coupled to the input node N1 of the control circuit 424, and a second input node NR coupled to a third node N3.

The control circuit comprises, for example, at least one flip-flop 428, 418, which couples a first output node NQ of the latch to the third node N3 and is configured to receive the first clock signal clk.

In the illustrated example, the control circuit comprises two flip-flops 428, 418 in series, coupling the first output node NQ of the latch to the third node N3. A first flip-flop 418 among these flip-flops is configured to receive the first clock signal clk. A second flip-flop 428 is configured to be controlled by a complementary signal clkb to the first clock signal clk.

In the illustrated example, control circuit 424 comprises a first logic circuit 426 configured to implement an XOR-type function between the signal present at third node N3 and the signal present at node N1. The node NRESET of the first logic circuit 426 is coupled to a second logic circuit 446 and a third logic circuit 456.

The second logic circuit 446 is configured to implement an OR-type function between the signal present at the node NRESET and the control signal φₚ. The signal present at the output of the second logic circuit 446 is a control signal φₚ.

The third logic circuit 456 is configured to implement an OR-type function between the signal present at the node NRESET and the control signal φₙ. The signal present at the output of the third logic circuit 456 is a control signal φₙ.

In the example shown in FIG. 4, the signal at the output node of the second logic circuit 446 is that which controls switches 225 and 222, and the signal at the output node of the third logic circuit 456 is that which controls switches 220 and 228.

When a variation in the input signal to the amplifier circuit 400 is detected at node NVout by the detection circuit, a pulse is then generated on the signal comp at the output of comparator 438, present at node N1. This triggers the start of a time window, the duration NTs of which depends, in the illustrated example, on the number N of flip-flops 418, 428 in series in the control circuit 424, and therefore depends on N periods of the clock signal clk (or its complementary clkb). The output is therefore synchronous with the notch filter clock, restarting on a native notch filter cycle. During this time window, control signals φₚ, φₙ are applied to switches 225 and 222, and 220 and 228, respectively.

In the illustrated example, the control signals φₚ, φₙ, for example, are of a high level if switches 225, 222, 220, and 228 are NMOS transistors, so that they turn on switches 225, 222, 220, and 228. The notch filter then becomes conductive, i.e., it is in track mode.

When the time window is over, the levels of the control signals φₚ, φₙ, applied to switches 225 and 222, and 220 and 228, are those of the control signals φₚ, φₙ, respectively. In other words, outside the time window triggered by the detection of the high-frequency component of the variation in the input voltage to amplifier circuit 400, the sampling mode described in FIG. 2 applies.

In a non-illustrated example, the serial flip-flops 418, 428 are replaced with a counter incremented by each clock stroke of the signal clk (or clkb), when the counter reaches a value N, then the signal reset at the node NRESET changes state and returns, for example, to the low state to close the time window and return the notch filter to sampling mode.

The value N can be programmed by a digital circuit external to the amplifier circuit 400, for example.

In an optional example, switches 434 and 450 are controlled by the signal reset present at node NRESET. Thus, following detection of the pulse component due to the rapid rate of variation in the input voltage to the amplifier circuit 400, the signal reset goes to high level, turning switches 434 and 450 on if they are NMOS transistors, for example. This allows the transfer function during the time window dedicated to the track mode of the notch filter to be improved by eliminating the zero induced by the presence of this resistor.

The example shown in FIG. 4 allows the settling time to be reduced by switching the notch filter to the track mode as soon as a rapid voltage variation is detected, which takes place in a time of less than 1 μs.

The example shown in FIG. 4 further allows the sampling mode to be synchronously resumed at the end of the time window dedicated to the track mode.

The example shown in FIG. 4 further allows a control circuit 424 to be implemented as a fully digital circuit.

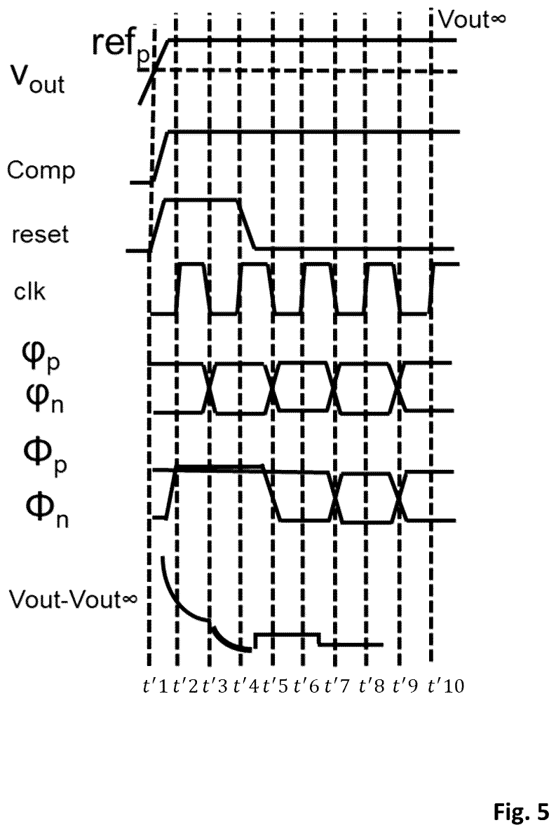

FIG. 5 illustrates an operating timing diagram for the circuit shown in FIG. 4.

More specifically, FIG. 5 illustrates the variations in the voltage Vout at the node NVout, the signal comp at the output of the comparator 438, the signal reset at the node NRESET, the clock signal clk, the signals φₚ, φₙ, the signals φₚ, φₙ, and the difference between the signal Vout and a signal Vout∞ being the voltage Vout once stabilized after a time, for example, of the order of milliseconds.

In the illustrated example, before a time t′1, a rapid voltage variation is present in the input voltage to the amplifier circuit 400. It causes the output level Vout to increase until it crosses the threshold refp at time t′1, thereby activating the track mode of the notch filter. Between times t′1 and t′2, the signal comp thus increases to the high level and then remains stable, the signal reset increases accordingly up to the high level, the clock signal clk is at the low level, the signal φₚ is at the high level, the signal φₙ is at low level, the signal φₚ is at high level, the signal φₙ increases accordingly from low level up to high level, and Vout−Vout∞ decreases, due to the action of amplifier 216, between time t′1 and up to a time t′3 after t′2.

Between time t′2 and time t′3, the signal clk provides a clock stroke, the signal Vout remains above refp and gradually approaches Vout∞, the signal reset remains at high level, the signal φₚ is at high level, the signal φₙ is at low level, the signal φₚ remains at high level, and the signal φₙ remains at high level so as to keep the notch filter in track mode.

Between time t′3 and a time t′4 after t′3, the signal clk remains low, the signal reset remains at high level, the signal φₚ drops to low level and remains there until a time t′5, the signal φₙ rises up to high level and remains there until time t′5, the signal φₚ remains at the high level, the signal φₙ remains at the high level, and Vout−Vout∞ decreases more rapidly this time due to the action of the first amplification path with the notch filter set to track mode.

Between time t′4 and time t′5, the signal clk provides a clock stroke, the signal reset drops to the low level, the signal φₚ rises to the high level until a time t′7, the signal φₙ goes to the low level and remains there until time t′7, the signal φₚ remains at the high level, the signal φₙ falls back to the low level to become synchronous with the signal φₙ, and Vout−Vout∞ is close to zero and oscillates following the error brought about by the notch filter, following approximately the periods of the signals φₙ and φₚ. From time t′5, the sampling mode is activated instead of the track mode, and the signals φₚ and φₙ are synchronous with the signals φₙ and φₚ, which oscillate in phase opposition with a period twice that of the signal clk.

In the example shown in FIG. 5, the time window over which the notch filter's track mode is implemented is the interval between times t′2 and t′5.

In one example, the signal comp can be reset to the low level after the signal reset has returned to the low level.

Various embodiments and variants have been described. Those skilled in the art will understand that certain features of these embodiments can be combined and other variants will readily occur to those skilled in the art. In particular, the detection circuit 406 is, for example, external to the amplifier circuit 400. On the other hand, even though the example shown in FIG. 4 describes a synchronous resumption of sampling mode at the end of the time window dedicated to track mode, those skilled in the art may envisage, instead of flip-flops 418 and 428, components, such as a counter, implementing the time window, so that the resumption of sampling mode at the end of the time window is asynchronous.

Finally, the practical implementation of the embodiments and variants described herein is within the capabilities of those skilled in the art based on the functional description provided hereinabove. In particular, the detection circuit may be coupled to a node other than node NVout, such as node N7, node N5, or even nodes N4 or NVIN. The detection circuit 406 can also be implemented using components other than those described, such as an active bypass function. Furthermore, the amplifier circuit 400 can be used for other types of amplifier circuits other than inverter or follower circuits.

What is claimed is:

1. An amplifier circuit, comprising:
an input node configured to receive a signal;
multiple amplification paths configured to amplify the signal, wherein a first amplification path includes a notch filter; and
a control circuit configured to:
turn the notch filter conductive in response to a rate of variation in voltage of the signal being greater than a slew rate of the amplifier circuit; and
control the notch filter in a sampling mode after a number of periods of a first clock signal of the amplifier circuit following turning the notch filter conductive.

2. The amplifier circuit of claim 1, wherein the number of periods of the first clock signal is programmable, and wherein the amplifier circuit further comprises:
an output node;
a detection circuit coupling the output node to an input node of the control circuit; and
a comparator circuit coupling a high-pass filter to the input node of the control circuit.

3. The amplifier circuit of claim 2, wherein the comparator circuit is configured to:
compare a signal at an output of the high-pass filter with one or more voltage thresholds, wherein the one or more voltage thresholds are programmed externally from the amplifier circuit; and
change a signal state at the input node of the control circuit in response to at least one of the one or more voltage thresholds being crossed, wherein the signal state is in a form of a pulse.

4. The amplifier circuit of claim 1, wherein the control circuit comprises a latch having a first input node and a second input node, the first input node coupled to an input node of the control circuit, the second input node coupled to a third node.

5. The amplifier circuit of claim 4, wherein the control circuit comprises a flip-flop coupling a first output node of the latch to the third node, the flip-flop configured to receive the first clock signal.

6. The amplifier circuit of claim 5,
wherein the control circuit comprises a plurality of flip-flops arranged in series,
wherein the plurality of flip-flops couple the first output node of the latch to the third node, and
wherein a first flip-flop is configured to receive the first clock signal, and a second flip-flop is configured to be controlled by a complementary signal to the first clock signal.

7. The amplifier circuit of claim 4, wherein the latch is of a Reset-Set (RS)-type.

8. The amplifier circuit of claim 4, wherein the control circuit comprises a first logic circuit configured to implement an XOR-type function between a signal at the third node and a signal at the input node of the control circuit.

9. The amplifier circuit of claim 8, wherein the notch filter comprises:
a first branch comprising a first switch and a second switch arranged in series between a fourth node and a fifth node of the first amplification path, the first switch and the second switch controlled by a first control signal and a second control signal, respectively, wherein a shared node between the first switch and the second switch is grounded through a first capacitor; and
a second branch comprising a third switch and a fourth switch arranged in series between the fourth and the fifth node, the third switch and the fourth switch controlled by the second control signal and the first control signal, respectively, wherein a shared node between the third switch and the fourth switch is grounded through a second capacitor,
wherein the control circuit is configured to generate the first control signal and the second control signal.

10. The amplifier circuit of claim 9, wherein the control circuit comprises:
a second logic circuit coupled to an output node of the first logic circuit, the second logic circuit configured to implement an OR-type function between a signal at the output node of the first logic circuit and a third control signal, a signal at an output node of the second logic circuit being the first control signal; and
a third logic circuit coupled to the output node of the first logic circuit, the third logic circuit configured to implement an OR-type function between the signal at the output node of the first logic circuit and a fourth control signal, a signal at an output of the third logic circuit being the second control signal,
wherein the third control signal and the fourth control signal are in phase opposition with a period twice the period of the first clock signal, and
wherein the third control signal and the fourth control signal are used for the sampling mode.

11. The amplifier circuit of claim 9, wherein the amplifier circuit further comprises:
a first resistor arranged in series with a third capacitor between the fourth node and a sixth node; and
a fifth switch arranged in parallel with the first resistor, wherein the fifth switch is configured to be controlled by the signal at the output node of the first logic circuit.

12. The amplifier circuit of claim 11, wherein the amplifier circuit further comprises:
a second resistor arranged in series with a fourth capacitor between a seventh node and the sixth node, wherein an output node of the first amplification path is a shared node between the second resistor and the fourth capacitor; and
a sixth switch arranged in parallel with the second resistor, the sixth switch configured to be controlled by the signal present at the output node of the first logic circuit.

13. The amplifier circuit of claim 12,
wherein the first amplification path comprises a first amplifier coupling a first chopper circuit and a second chopper circuit,
wherein the first chopper circuit is configured to implement a modulation,
wherein the second chopper circuit is configured to implement a demodulation, and
wherein the first chopper circuit and the second chopper circuit are configured to operate at a frequency of the first clock signal.

14. The amplifier circuit of claim 13,
wherein the first amplification path comprises a second amplifier coupling the fifth node to the seventh node,
wherein a second amplification path comprises a third amplifier coupling the seventh node to an input node of the multiple amplification paths, and
wherein a fourth amplifier of the multiple amplification paths couples the sixth node to the seventh node.

15. A method for operating an amplifier circuit, the method comprising:
receiving a signal at an input node of the amplifier circuit;
amplifying the signal at multiple amplification paths of the amplifier circuit, wherein a first amplification path includes a notch filter; and
turning, by a control circuit of the amplifier circuit, the notch filter conductive in response to a rate of variation in voltage of the signal being greater than a slew rate of the amplifier circuit; and
controlling, by the control circuit, the notch filter in a sampling mode after a number of periods of a first clock signal of the amplifier circuit following turning the notch filter conductive.

16. The method of claim 15, wherein the number of periods of the first clock signal is programmable, and wherein the amplifier circuit further comprises:
an output node;
a detection circuit coupling the output node to an input node of the control circuit; and
a comparator circuit coupling a high-pass filter to the input node of the control circuit.

17. The method of claim 16, further comprising:
comparing, by the comparator circuit, a signal at an output of the high-pass filter with one or more voltage thresholds, wherein the one or more voltage thresholds are programmed externally from the amplifier circuit; and
changing, by the comparator circuit, a signal state at the input node of the control circuit in response to at least one of the one or more voltage thresholds being crossed, wherein the signal state is in a form of a pulse.

18. The method of claim 15,
wherein the control circuit comprises a latch having a first input node and a second input node, the first input node coupled to an input node of the control circuit, the second input node coupled to a third node,
wherein the control circuit comprises a flip-flop coupling a first output node of the latch to the third node, the flip-flop configured to receive the first clock signal,
wherein the control circuit comprises a plurality of flip-flops arranged in series,
wherein the plurality of flip-flops couple the first output node of the latch to the third node, and
wherein a first flip-flop is configured to receive the first clock signal, and a second flip-flop is configured to be controlled by a complementary signal to the first clock signal.

19. The method of claim 18, wherein the control circuit comprises a first logic circuit configured to implement an XOR-type function between a signal at the third node and a signal at the input node of the control circuit.

20. A control circuit for operating an amplifier circuit, the control circuit configured to:
turn a notch filter conductive in response to a rate of variation in voltage of a signal at an input node of the amplifier circuit being greater than a slew rate of the amplifier circuit, wherein the amplifier circuit comprises multiple amplification paths for amplifying the signal, wherein a first amplification path includes the notch filter; and
control the notch filter in a sampling mode after a number of periods of a first clock signal of the amplifier circuit following turning the notch filter conductive.
